(19) United States
(12) Patent Application Publication
(10) Pub. No.: US 2013/0092236 A1
(43) Pub. Date: Apr. 18, 2013

(54) SOLAR CELLS

(71) Applicant: Kyung Hyun KIM, Daejeon (KR)

(72) Inventor: Kyung Hyun KIM, Daejeon (KR)

(73) Assignee: ELECTRONICS AND TELECOMMUNICATIONS RESEARCH INSTITUTE, Daejeon (KR)

(21) Appl. No.: 13/493,543

(22) Filed: Jun. 11, 2012

(30) Foreign Application Priority Data
Oct. 14, 2011 (KR) 10-2011-0105062

(51) Int. Cl. H01L 31/0224; H01L 31/04; H01L 31/0272; B82Y 30/00

(52) U.S. Cl. 136/262; 136/252; 136/264; 136/265; 977/742; 977/750; 977/748; 977/948

(57) ABSTRACT

Solar cells are provided. The solar cell may include a substrate, a first electrode, a light absorption layer, a second electrode. Additionally, an intrinsic layer and a buffer layer may further be disposed between the light absorption layer and the second electrode. Here, the first and second electrodes may consist of carbon nanotubes of which polarities may be controlled. Thus, a flexible solar cell of low costs and high efficiency may be realized.

### CROSS-REFERENCE TO RELATED APPLICATIONS

This U.S. non-provisional patent application claims priority under 35 U.S.C. §119 to Korean Patent Application No. 10-2011-0105062, filed on Oct. 14, 2011, the entirety of which is incorporated by reference herein.

### BACKGROUND

The inventive concept relates to solar cells and, more particularly, to copper-indium-gallium-selenium (CIGS) solar cells having electrodes using a carbon nanotube.

Recently, new renewable energies have been watched with keen interest because of energy problems and global warming problems. Particularly, solar cells convert sunlight into electric energy. The sunlight used as a source of the solar cells may not be exhausted and may be friendly to environment. Thus, the solar cells are attractive in a new renewable energy industry.

The solar cells can be categorized as any one of crystalline silicon solar cells using a wafer used as a semiconductor device and thin film solar cells using a deposition technique performed on a substrate such as a glass. The thin film solar cells use a low cost substrate such as the glass, differently from an absorption substrate fully formed of crystalline silicon.

The thin film solar cells may classified into an amorphous silicon thin film solar cells, a compound thin film solar cells using CdTe or CIGS, dye-sensitized thin film solar cells, and organic thin film solar cells according to kinds of materials of light absorption layers. Additionally, solar cells having tandem structures have been suggested for improving efficiency of the amorphous silicon thin film solar cells.

The thin film solar cell may include a metal electrode used as a lower electrode and a transparent electrode used as an upper electrode. Generally, indium tin oxide (ITO) may be easily formed on the glass substrate and have excellent light transmittance and conductivity. Thus, the transparent electrode may be formed of the ITO. Vacuum deposition apparatuses may be used for manufacturing the ITO electrode. Particularly, sputtering apparatuses with excellent characteristic of the vacuum deposition apparatus may be mainly used for manufacturing the ITO electrode. If the transparent electrode is formed by the sputtering apparatus, a process temperature may be about 200 degrees Celsius or more, or about 400 degrees Celsius at times. Thus, it may be difficult to apply the sputtering apparatus to manufacturing of a flexible display. Moreover, the ITO electrode may have low flexibility. If the ITO electrode is applied to the flexible display, a surface resistance may increase and durability thereof may deteriorated.

For resolving the above problems, various researches have been conducted for using carbon nanotube (CNT) having high electric conductivity as the transparent electrode. The carbon nanotube may have various physical and chemical properties. Additionally, the carbon nanotube may have an n-type polarity or a p-type polarity. Thus, the carbon nanotube may be variously applied to the solar cells.

### SUMMARY

Embodiments of the inventive concept may provide flexible solar cells of which light transmittance and electric conductivity are excellent.

Embodiments of the inventive concept may also provide solar cells capable of controlling polarity of carbon nanotube electrodes to reduce interface defects.

In one aspect, a solar cell may include: a substrate; a first electrode on the substrate; a light absorption layer on the first electrode; and a second electrode on the light absorption layer. The first electrode may be a p-type carbon nanotube layer and the second electrode may be an n-type carbon nanotube layer.

In some embodiments, the first electrode may include a single wall carbon nanotube or a carbon nanotube on which a halogen element is bonded. The halogen element may be bromine (Br) or iodine (I).

In other embodiments, the second electrode may include a carbon nanotube on which oxygen or alkali metal is bonded. The alkali metal may be one of be potassium (K), sodium (Na), and cesium (Cs).

In still other embodiments, the solar cell may further include: a buffer layer between the light absorption layer and the second electrode; and an intrinsic layer between the buffer layer and the second electrode.

In yet other embodiments, the light absorption layer may include a chalcopyrite based compound semiconductor including at least one of CuInSe, CuInSe₂, CuInGaSe, and CuInGaSe₂.

In yet still other embodiments, the intrinsic layer may include zinc oxide (ZnO).

In another aspect, a solar cell may include: a substrate; a first electrode on the substrate; a light absorption layer on the first electrode; and a second electrode on the light absorption layer. The first electrode may be an n-type carbon nanotube layer and the second electrode may be a p-type carbon nanotube layer.

In some embodiments, the second electrode may include a single wall carbon nanotube or a carbon nanotube on which a halogen element is bonded.

In other embodiments, the first electrode may include a carbon nanotube on which oxygen or alkali metal is bonded.

### BRIEF DESCRIPTION OF THE DRAWINGS

The inventive concept will become more apparent in view of the attached drawings and accompanying detailed description.

FIG. 1 is a cross-sectional view illustrating a general copper-indium-gallium-selenium (CIGS) solar cell;

FIG. 2 is a cross-sectional view illustrating a solar cell according to a first embodiment of the inventive concept;

FIG. 3 is a cross-sectional view illustrating a solar cell according to a second embodiment of the inventive concept; and

FIG. 4 is a cross-sectional view illustrating a solar cell according to a third embodiment of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms.

Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

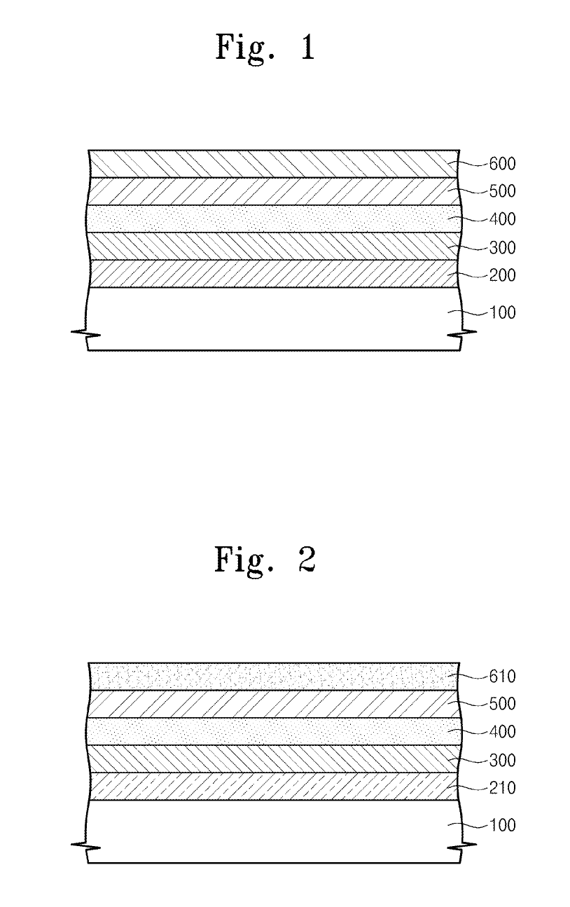

FIG. 1 is a cross-sectional view illustrating a general CIGS solar cell.

Referring to FIG. 1, a metal electrode 200, a CIGS light absorption layer 300, a buffer layer 400, an intrinsic layer 500, and a transparent electrode 600 may be sequentially stacked on a substrate 100.

The metal electrode 200 may be formed of a material having high electric conductivity, an ohmic contact characteristic with respect to another layer, and high stability under a selenium (Se) environment. For example, the metal electrode 200 may be formed of molybdenum (Mo). Molybdenum may be deposited on the substrate 100 in a vacuum state by a DC sputtering method.

The transparent electrode 600 may be formed of a material having high light transmittance and good electric conductivity. For example, the transparent electrode 600 may be formed of a zinc oxide (ZnO) layer. The zinc oxide layer may have an energy band gap of about 3.2 eV and a high light transmittance of about 80% or more. If the zinc oxide layer is doped with aluminum or boron, the zinc oxide layer may have low resistance. Alternatively, the transparent electrode 600 may include indium tin oxide (ITO) having excellent electric and optical characteristics.

FIG. 2 is a cross-sectional view illustrating a solar cell according to a first embodiment of the inventive concept.

Referring to FIG. 2, a solar cell according to a first embodiment of the inventive concept may have a substrate type stack structure. A first electrode 210, a CIGS light absorption layer 300, a buffer layer 400, an intrinsic layer 500, and a second electrode 610 may be sequentially stacked on a substrate 100. A metal electrode pad for connection with outside of the solar cell may be disposed on the second electrode 610.

The substrate 100 may be a transparent substrate. The substrate 100 may be a transparent inorganic substrate such as quartz or glass. If a sodalime glass is used as the substrate 100, sodium of the sodalime glass may be diffused into the CIGS light absorption layer 300 during manufacture of the solar cell. A concentration of charges of the CIGS light absorption layer 300 may increase by the diffusion of the sodium. Thus, a photoelectric conversion efficiency of the solar cell may increase. The substrate 100 may be a transparent plastic substrate formed of polyethylene terephalate (PET), polyethylene naphthalate (PEN), polystyrene, polypropylene polyester, polyimide, polyetherimide, acrylic resin, olefin-maleimide copolymer, and/or norbornene-based resin. If the substrate 100 may be a flexible substrate, the solar cell having flexibility may be manufactured.

The first electrode 210 may be a p-type carbon nanotube layer, and the second electrode 610 may be an n-type carbon nanotube layer. After carbon nanotubes formed by an arc discharge method may be evenly mixed into a solution of water and a dispersant, the solution including the carbon nanotube, the water, and the dispersant may be sprayed on the substrate 100 and then be dried. Thus the carbon nanotube layer may be formed. In other embodiments, the carbon nanotube layer may be formed by a laser deposition method, a plasma chemical vapor deposition method, a thermal chemical vapor deposition method, a vapor phase growth method, an electrolysis method, or a flame synthesis method. The dispersant having electric conductivity may be used for improve electric conductivity of the carbon nanotube transparent electrode. For example, the dispersant may include at least one of polythiophene, polyaniline, and 4-phenylvinylene.

The carbon nanotubes may be classified into three kinds of carbon nanotubes having metallic property, carbon nanotubes having semi-metallic property, and carbon nanotubes having semiconducting property. The carbon nanotubes of armchair without chirality may correspond to metallic carbon nanotubes having an energy band bap of about 0 (zero). The carbon nanotubes may be classified into the carbon nanotubes having semi-metallic property and the carbon nanotubes having semiconducting property according to an intensity degree of chirality. A single wall carbon nanotube of the carbon nanotubes having semiconducting property may mainly correspond to a p-type semiconductor, and a double wall carbon nanotube of the carbon nanotubes having semiconducting property may correspond to an ambipolar semiconductor having p-type property and n-type property. Additionally, the carbon nanotube may be changeable to p-type or n-type according to a material bonded to an outer wall of the carbon nanotube.

The p-type carbon nanotube layer may include the single wall carbon nanotube having the p-type. Alternatively, the p-type carbon nanotube layer may include the carbon nanotube on which halogen element is bonded. The halogen element may be bromine (Br) or iodine (I). The n-type carbon nanotube layer may include the carbon nanotube on which oxygen or alkali metal is bonded. The alkali metal may be potassium (K), sodium (Na), or cesium (Cs). A doping method for bonding the alkali metal on the carbon nanotube may be performed using a gas injection method.

If the solar cell of FIG. 2 according to the first embodiment is compared with the general solar cell of FIG. 1, the first electrode 210 corresponding to the p-type carbon nanotube layer may be substituted for the metal electrode 200 of FIG. 1 and the second electrode 610 corresponding to the n-type carbon nanotube layer may be substituted for the transparent electrode 600 of FIG. 1. The polarity of the first electrode 210 may be the same as that of the CIGS light absorption layer 300 and the polarity of the second electrode 610 may be the same as that of the intrinsic layer 500. Thus, interface defects may be reduced. If the interface defects increase, carries may be reduced by the interface defects, such that a light absorption rate of a solar cell may decrease. However, in the present embodiments, since the interface defects are reduced, the light absorption rate of the solar cell may increase.

The CIGS light absorption layer 300 may absorb sunlight inputted from the outside of the solar cell. The CIGS light absorption layer 300 may be formed of I-II-VI2 group compound semiconductor. For example, the CIGS light absorption layer 300 may be formed of chalcopyrite-based compound semiconductor including at least one of CuInSe₂, Cu(In,Ga)Se₂, Cu(Al,In)Se₂, Cu(Al,Ga)Se₂, Cu(In,Ga)(S,Se)₂, and (Au,Ag,Cu)(In,Ga,Al)(S,Se)₂. The above compound semiconductors described as examples may be commonly known as CIGS thin films. In some embodiments, the CIGS light absorption layer 300 may include CuInGaSe₂ having an energy band gap of about 1.2 eV.

In some embodiments, the CIGS light absorption layer 300 may be deposited by a co-evaporation method using four metal elements (e.g., copper (Cu), indium (In), gallium (Ga), selenium (Se)) as starting elements. In other embodiments, the CIGS light absorption layer 300 may be deposited by sputtering and selenizing the four metal elements or compounds thereof. In still other embodiments, the process forming the CIGS light absorption layer 300 may not use a vacuum apparatus. In other words, after chalcogenide compound or precursor nano particles are formed, the CIGS light absorption layer 300 may be formed by a wet method such as a printing process.

A thickness of the CIGS light absorption layer 300 may have a range of about 0.5 μl to about 10 μm. However, the inventive concept is not limited thereto. The CIGS light absorption layer 300 may have p-type polarity. The CIGS light absorption layer 300 may be deposited on a zinc sulfide (ZnS) layer (not shown) and then be thermally treated. Thus, zinc may be diffused into the CIGS light absorption layer 300, so that a portion of the CIGS light absorption layer 300 adjacent to the ZnS layer may become n-type. In this case, p-n homojunction may be formed in the CIGS light absorption layer 300. Thus, the photoelectric conversion efficiency may be improved.

Since the CIGS light absorption layer 300 may have p-type semiconductor property and the intrinsic layer 500 and the second electrode 610 may have n-type semiconductor property, difference between lattice constants of the CIGS light absorption layer 300 and the intrinsic layer 500 may be great, and difference between energy band gaps of the CIGS light absorption layer 300 and the intrinsic layer 500 may be great. The intrinsic layer 500 may not be doped with n-type and p-type impurities. However, the intrinsic layer 500 may have the n-type semiconductor property. This will be described in more detail below. Thus, the buffer layer 400 may be disposed between the CIGS light absorption layer 300 and the intrinsic layer 500 for buffering the differences. The buffer layer 400 may increase an adhesive force between the CIGS light absorption layer 300 and the intrinsic layer 500, such that peeling may be prevented. Thus, stability of the solar cell may be improved. An energy band gap of the buffer layer 400 may have a value between the energy band gaps of the CIGS light absorption layer 300 and the intrinsic layer 500. The buffer layer 400 may be formed by a chemical bath deposition (CBD) method. The buffer layer 400 may be formed of cadmium sulfide (CdS).

The cadmium sulfide (CdS) may have an energy band gap of about 2.46 eV corresponding to a wavelength of about 550 nm. For lowering a resistance of the cadmium sulfide (CdS), the cadmium sulfide (CdS) may be doped with indium (In), gallium (Ga), and/or aluminum (Al). Alternatively, the buffer layer 400 may be formed of at least one of ZnS, MnS,Zn(O,S), ZnSe, (Zn, In)Se, and In(OH,S) which do not include cadmium (Cd) corresponding to a heavy metal.

The intrinsic layer 500 may reduce recombination rate of carriers and correspond to a path through which holes are moved. The intrinsic layer 500 may be formed of zinc oxide (ZnO). Intrinsic zinc oxide may not be doped with n-type and p-type impurities. However, the amount of oxygen in the intrinsic zinc oxide may be lacked, such that oxygen vacancies may exist in the intrinsic zinc oxide. The oxygen vacancies may exhibit n-type property. Thus, the solar cell according to the first embodiment may fully constitute p-n junction.

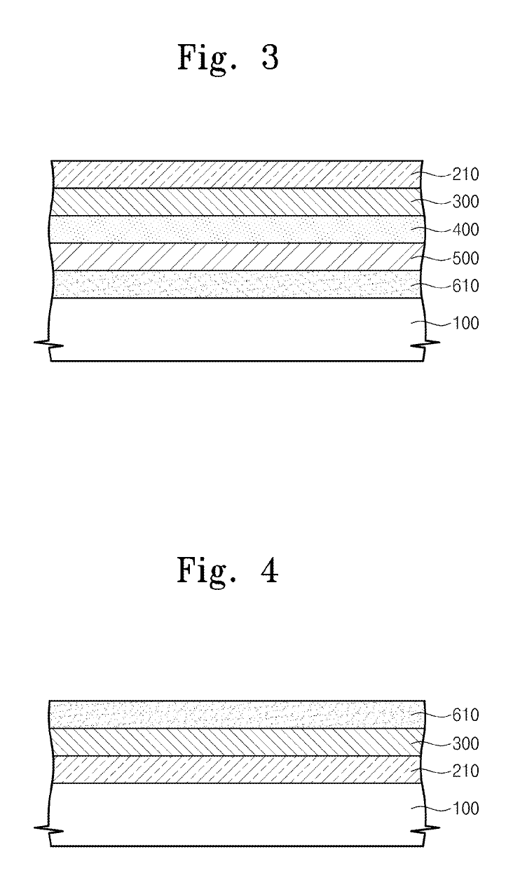

FIG. 3 is a cross-sectional view illustrating a solar cell according to a second embodiment of the inventive concept.

Referring to FIG. 3, the second electrode 610 of the n-type carbon nanotube, the intrinsic layer 500, the buffer layer 400, the CIGS light absorption layer 300, and the first electrode 210 of the p-type carbon nanotube may be sequentially stacked on the substrate 100. The metal electrode pad for connection with outside of the solar cell may be disposed on the first electrode 210 corresponding to an upper transparent electrode.

FIG. 4 is a cross-sectional view illustrating a solar cell according to a third embodiment of the inventive concept.

A solar cell illustrated in FIG. 4 may include the first electrode 310, the CIGS light absorption layer 300, and the second electrode 610 which are sequentially stacked on the substrate 100. The solar cell of FIG. 4 may not include the buffer layer and the intrinsic layer, differently from the solar cell of FIG. 2. Since the carbon nano tube may have the polarity by a doping method, the n-type carbon nanotube layer may function as the buffer layer.

According to embodiments of the inventive concept, the carbon nanotubes may be used as the electrodes of the solar cell. The carbon nanotube may have excellent electric conductivity and excellent light transmittance. Thus, the efficiency of the solar cell may increase and the solar cell may become lighter. Additionally, since the carbon nanotube is flexible, a flexible solar cell may be realized. Moreover, since the carbon nanotube is stable at a high temperature, the carbon nanotube may be applied to the solar cell having a wide energy band gap and the tandem structure solar cell. The polarity of the carbon nanotube may be controlled to have the n-type or the p-type. Thus, the interface characteristic may be improved to increase the efficiency of the solar cell.

Additionally, the electrodes of the solar cell may be manufactured in a non-vacuum state. Thus, the process time for the formation of the solar cell may be reduced and manufacture costs of the solar cell may be reduced.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A solar cell comprising:
a substrate;
a first electrode on the substrate;
a light absorption layer on the first electrode; and
a second electrode on the light absorption layer,
wherein the first electrode is a p-type carbon nanotube layer and the second electrode is an n-type carbon nanotube layer.

2. The solar cell of claim 1, wherein the first electrode includes a single wall carbon nanotube or a carbon nanotube on which a halogen element is bonded.

3. The solar cell of claim 2, wherein the halogen element is bromine (Br) or iodine (I).

4. The solar cell of claim 3, wherein the second electrode includes a carbon nanotube on which oxygen or alkali metal is bonded.

5. The solar cell of claim 4, wherein the alkali metal is one of be potassium (K), sodium (Na), and cesium (Cs).

6. The solar cell of claim 5, further comprising:
a buffer layer between the light absorption layer and the second electrode; and
an intrinsic layer between the buffer layer and the second electrode.

7. The solar cell of claim 6, wherein the light absorption layer includes a chalcopyrite based compound semiconductor including at least one of CuInSe, CuInSe₂, CuInGaSe, and CuInGaSe₂.

8. The solar cell of claim 6, wherein the intrinsic layer includes zinc oxide (ZnO).

9. A solar cell comprising:
a substrate;
a first electrode on the substrate;
a light absorption layer on the first electrode; and
a second electrode on the light absorption layer,
wherein the first electrode is an n-type carbon nanotube layer and the second electrode is a p-type carbon nanotube layer.

10. The solar cell of claim 9, wherein the second electrode includes a single wall carbon nanotube or a carbon nanotube on which a halogen element is bonded.

11. The solar cell of claim 10, wherein the first electrode includes a carbon nanotube on which oxygen or alkali metal is bonded.
